(19) United States
(12) Patent Application Publication
(10) Pub. No.: US 2026/0018432 A1
(43) Pub. Date: Jan. 15, 2026

(54) SEMICONDUCTOR VAPOR ETCHING DEVICE WITH INTERMEDIATE CHAMBER

(71) Applicant: ASM IP Holding B.V., Almere (NL)

(72) Inventors: Tom E. Blomberg, Vantaa (FI); Varun Sharma, Helsinki (FI)

(21) Appl. No.: 19/332,551

(22) Filed: Sep. 18, 2025

Related U.S. Application Data
(63) Continuation of application No. 16/930,867, filed on Jul. 16, 2020.
(60) Provisional application No. 62/875,910, filed on Jul. 18, 2019.

(51) Int. Cl. H01L 21/67; H01L 21/3065

(52) U.S. Cl. CPC H01L 21/67069; H01L 21/3065; H01L 21/67017

(57) ABSTRACT

A semiconductor vapor etching device is disclosed. The device can include an intermediate chamber between a vapor source and a reaction chamber. Etch reactant vapor can be pulsed from the intermediate chamber to the reaction chamber to etch a substrate.

### CROSS-REFERENCE TO RELATED APPLICATIONS

This application is a continuation of and claims priority to U.S. patent application Ser. No. 16/930,867 filed Jul. 16, 2020, titled “SEMICONDUCTOR VAPOR ETCHING DEVICE WITH INTERMEDIATE CHAMBER” which claims priority to U.S. Provisional Patent Application No. 62/875,910 filed Jul. 18, 2019, titled “SEMICONDUCTOR VAPOR ETCHING DEVICE WITH INTERMEDIATE CHAMBER” the contents of each of which is incorporated by reference herein in its entirety and for all purposes.

### BACKGROUND

### Field

The field relates to a semiconductor processing device with an intermediate chamber, and, more particularly, to an etch reactor with an intermediate chamber.

### Description of the Related Art

Controlled removal of materials in semiconductor processing is highly desirable. Chemical vapor etching (CVE) or atomic layer etching (ALE) can have advantages over plasma systems, but in both thermal and plasma etching, it can be challenging to provide uniform etching effects across large substrates, even more so when the substrate has significant topography.

### SUMMARY

According to one aspect, a semiconductor etching device is disclosed. The device can comprise: a reaction chamber; an intermediate chamber upstream of and in fluid communication with the reaction chamber, the intermediate chamber being configured to deliver an etch reactant vapor to the reaction chamber; a source of etch reactant vapor upstream of and in fluid communication with the intermediate chamber, the source being configured to deliver the etch reactant vapor to the intermediate chamber; a first valve disposed along a reactant supply line between the source and the intermediate chamber, the first valve being configured to regulate a flow of the etch reactant vapor to the intermediate chamber; and a second valve disposed along the reactant supply line between the intermediate chamber and the reaction chamber, the second valve being configured to regulate a flow of the etch reactant vapor to the reaction chamber.

According to one aspect, a semiconductor etching device is disclosed. The device can comprise: a reaction chamber; an intermediate chamber upstream of and in fluid communication with the reaction chamber, the intermediate chamber being configured to deliver an etch reactant vapor to the reaction chamber; and a control system that is configured to pulse the etch reactant vapor into the reaction chamber from the intermediate chamber.

According to one aspect, a method of etching a substrate is disclosed. The method can comprise: supplying an etch reactant vapor to an intermediate chamber; and pulsing at least a portion of the etch reactant vapor from the intermediate chamber to a reaction chamber downstream of the intermediate chamber.

### BRIEF DESCRIPTION OF THE DRAWINGS

These and other features, aspects and advantages of the present invention will now be described with reference to the drawings of several embodiments, which embodiments are intended to illustrate and not to limit the invention.

FIG. 1 is a schematic system diagram of a semiconductor processing device during a filling stage, according to various embodiments.

FIG. 2 is a schematic system diagram of a semiconductor processing device during a first example of a pulsing mode, according to an embodiment.

FIG. 3 is a schematic system diagram of a semiconductor processing device during a second example of a pulsing mode, according to an embodiment.

FIG. 4 is a schematic system diagram of a semiconductor processing device during a third example of pulsing mode, according to an embodiment.

### DETAILED DESCRIPTION

A sub-monolayer or more of material can be removed from a substrate by chemical vapor etching (CVE). Pulsing vapor etch reactants (such as an adsorbing reactant and/or an etchant) can provide additional parameters to modulate and greater control over the etch process to achieve the desired distribution across large substrates used in state-of-the-art semiconductor processing. In some pulsed etching processes, one or more vapor phase reactants can be employed in sequential pulses. For example, a reactant can adsorb in one pulse, followed by a second reactant that forms volatile by-products that contain the adsorbate atoms, the second reactant and some atoms from the surface being etched. In this way the etching of the desired material on the substrate surface can be carefully controlled. Additional systems and methods for such pulsed and cyclical etching processes are shown and described in U.S. Pat. No. 10,273,584, which is also incorporated by reference herein in its entirety and for all purposes.

Thermal chemical etching of microelectronics materials may have benefits over plasma etching processes. However, in order to have uniform etch rates across the wafer, the partial pressures, residence times and temperatures of the etch reactant (e.g., etchant and/or other reactants) and by-products should not vary spatially above the wafer. In cases where surface control is lacking in the etch reaction, the etch per cycle (EPC) can still be controlled, for example, by dose starvation. Dose starvation involves limiting the number of molecules injected in the reactor in each etch pulse or cycle, which also limits the depth of penetration within the substrate. Therefore, pulsed etching with accurate dose control can function provide greater etch process control, whether or not involving multiple reactants. However, the dosage should preferably be distributed uniformly over the substrate in order to etch uniformly large area substrates.

A system configuration that uses a pulsing method, in which the total dosage and the partial pressure during the pulse can be separately controlled, can assist with uniformly etching large area substrates. The dosage can determine the EPC in the process, whereas the partial pressure behavior during the pulse can determine the uniformity of the etching. In some embodiments, partial pressure/total pressure pulsing is used instead of continuous flow etching. Pulsing the etch reactant into the reactor can increase convection and diffusion transport velocities in the reactor and, therefore, may result in more conformal etching than a continuous flow (steady state) etching process.

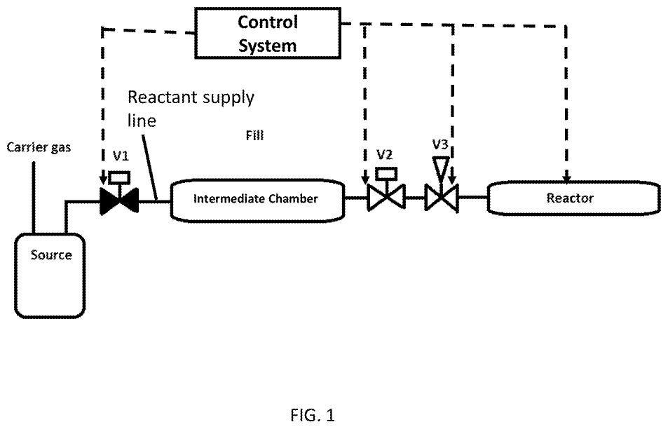

FIGS. 1-4 illustrate a system configuration 1 that incorporates various pulsing methods. In some embodiments, the system configuration 1 comprises a carrier gas line 2, a reactant source 3 downstream of and in fluid communication with the carrier gas line 2, an intermediate chamber 4 downstream of the source 3, a reactor 5 downstream of the intermediate chamber 4, and a plurality of valves, V1, V2, and V3. A reactant supply line 6 connects the source 3 to the intermediate chamber 4, with the valve V1 installed on the reactant supply line 6 between the source 3 and the intermediate chamber 4. The reactant supply line 6 connects the intermediate chamber 4 to the reactor 5, with a plurality of valves V2 and V3 installed on the line 6 between the intermediate chamber 4 and the reactor 5. The valves V1, V2, and V3 can comprise any suitable type of valve. For example, in various embodiments, the valves V1 and V2 can comprise an adjustable valve having a plurality of flow conductances. In some embodiments, the valves V1 and V2 can comprise a binary on/off valve. In some embodiments, valve V3 can comprise a needle valve that can be adjusted to a desired flow conductance. As shown in FIGS. 1-4, a control system 7 can include processing circuitry configured to control the operation (e.g., opening and/or closing) of the valves V1, V2, V3, and/or the operation of other components of the system, such as components of the reactor. Although not illustrated, the control system 7 can also be in electrical communication with various types of sensors, including, e.g., pressure sensors configured to monitor a pressure of the intermediate chamber 4, the source 3, the reactor 5, or any other suitable component or gas line of the system. The control system 7 can electrically communicate with other components, such as heaters. Furthermore, although not shown, a filter can be provided in the system 1, e.g., upstream of the intermediate chamber 4 and/or upstream of any of the valves V1, V2, V3.

In some embodiments, the source 3 comprises a vaporizer configured to convert a liquid or solid material to a vapor. For example, the source 3 can include a bubbler, evaporator, liquid injector, solid source sublimator, etc. The source 3 can supply a vaporized reactant to the reactant supply line 6. In various embodiments, the source 3 can contain a reactant for an etch process (e.g., an etchant). A carrier gas can be employed with a vaporizer as shown, and can also be employed to carry/dilute a naturally gaseous reactant. In other embodiments, no carrier gas is employed.

In some embodiments, the system configuration 1 does not comprise a source for plasma, radicals or excited species. In some embodiments, the system configuration 1 does not comprise a RF, microwave or ICP source for formation of plasma, radicals or excited species. In some embodiments, the system configuration 1 is not compatible or cannot be used for plasma based processes.

FIG. 1 illustrates the system 1 in a filling stage, in which vaporized reactant is supplied to and held within the intermediate chamber 4. For example, in FIG. 1, the valve V1 can open to fill the intermediate chamber 4 to a desired pressure with a mixture of carrier gas and vaporized reactant. In some embodiments, the valve V1 can be an adjustable valve that can control the flow conductance of the vaporized reactant. The intermediate chamber 4 can comprise a chamber that can ensure the reactant remains in vapor form for delivery to the reactor 5. In some embodiments, the control system 7 can also meter or control the amount of reactant vapor that is supplied to the reactor 5, for example, by opening and closing one or more of the valves V1, V2. Accordingly, the control system 7 can be configured to control the pulse-width and timing of pulse delivery to the reactor 5. In some embodiments, the pulse to the reactor 5 can have a pulse width in a range of about 0.001 seconds to 60 seconds. For example, the pulse width can be in a range of about 0.01 seconds to 10 seconds, in a range of about 0.05 seconds to 10 seconds, or in a range of about seconds to 5 seconds. In some embodiments, the partial pressures associated with a pulse-height of the pulse can be in a range of about 0.001 mbar to 100 mbar. For example, the partial pressures associated with the pulse-height of the pulse can be in a range of about 0.05 mbar to 50 mbar, or in a range of about 0.1 mbar to 20 mbar. The valve V2 can be opened to supply the reactor 5 with a mixture of carrier gas and vaporized reactant. In some embodiments, the valve V2 can be an adjustable valve that can control the flow conductance of the vaporized reactant. In some embodiments, the valve V3 can be a needle valve that controls the flow conductance of the vaporized reactant.

In some embodiments, the system configuration 1 can include one or a plurality of thermal zones that are maintained at various temperatures by heaters or other heating equipment. In some embodiments, there may be separate thermal zones for the vaporizer, the intermediate chamber 4, and the reaction chamber, with each thermal zone having a first, second, and third temperature respectively. In some embodiments, the first, second and third temperatures are about equal. In some embodiments, the second temperature of the second thermal zone can be higher than the first temperature of the first thermal zone. In various embodiments, for example, the second temperature can be higher than the first temperature by a temperature difference in a range of 5° C. to 50° C., in a range of 5° C. to 35° C., or in a range of 10° C. to 25° C. In some embodiments, the first temperature of the first thermal zone can be higher than the second temperature of the second thermal zone. In some embodiments, portions of the carrier gas line 2 can be provided with heater jackets to maintain the line 2 at or above the temperature of its respective thermal zone and above the reactant condensation temperature.

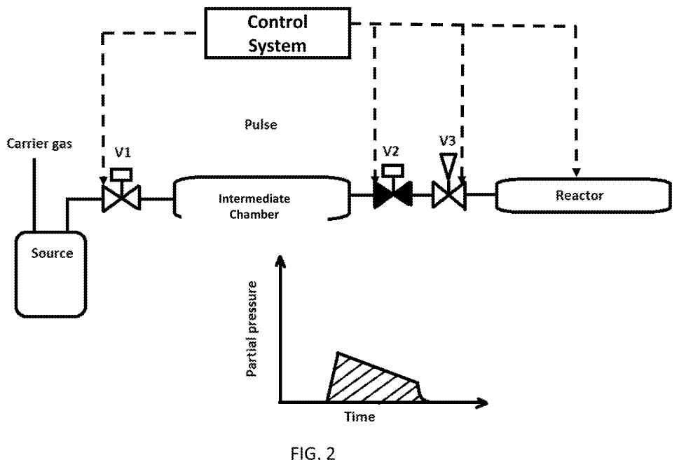

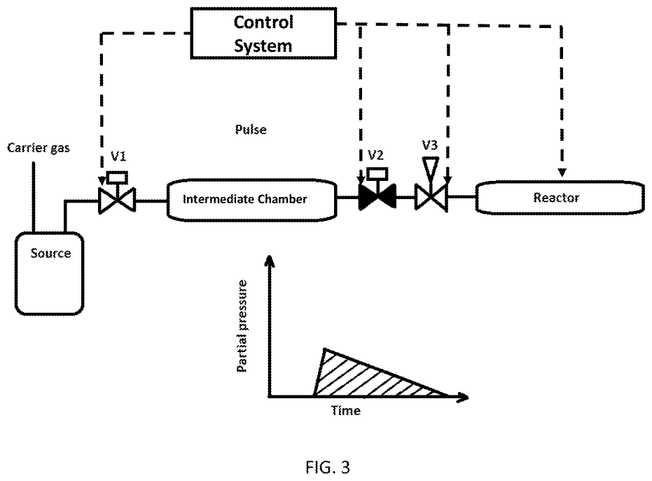

The system 1 can operate in various etching modes. In FIG. 1, the intermediate chamber 4 can be filled with vaporized reactant and carrier gas to a desired or set point pressure, which can be correlated to a desired reactant partial pressure. The reactant vapor can be vaporized at the source 3. A mixture of the vaporized reactant and the carrier gas can be carried, when the valve V1 is opened, along the reactant supply line 6 and delivered to the intermediate chamber 4. The intermediate chamber 4 can be filled to a pressure of P1 and then the valve V1 can be closed, as shown in FIGS. 2-3. The dosage of vaporized reactant in the intermediate chamber 4 can be determined by the equation nR=P1V/T.

FIG. 2 illustrates a first etching mode, in which a first type or shape of pulse is delivered to the reactor 5. As explained above, the valve V1 can be closed, the valve V2 can be at least partially opened. A portion of the dosage of reactant vapor contained in the intermediate chamber 4 can be transported to the reactor 5. Partial pressure of the reactant during the pulse period can be determined at least in part by the conductance of the needle valve V3 and the difference in pressure between the pressure in the intermediate chamber 4, P1, and the pressure in the reactor 5, P2. In some embodiments, the pressure P1 can be in a range of about 0.001 mbar to 100 mbar. For example, the pressure P1 can be in a range of about 0.05 mbar to 50 mbar or in a range of about 0.1 mbar to 20 mbar. In some embodiments, the pressure P2 can be in a range of about 0.001 mbar to 100 mbar. For example, the pressure P2 can be in a range of about 0.05 mbar 50 mbar, or in a range of about 0.1 mbar to 20 mbar. In various embodiments, the ratio of P1 to P2 can be less than about: 100:1, 50:1, 10:1, 5:1, 3:1, 2:1, 1.5:1, 1.25:1, or 1.1:1. The difference in pressure is determined by the equation ΔP=P1−P2. During operation, the pressure differential ΔP constantly changes as the pressure P1 decreases after opening the valve V2. Accordingly, partial pressure of reactant in the reaction chamber 5 can also vary as a function of time and can also be linear if the conductance is kept constant during the pulse. As depicted in FIG. 2, the precursor tail at the end of the pulse may be caused by bleeding of the precursor gas from the volume between V2 and V3 after shutting off V2. In some embodiments, the partial pressure at the last half of the pulse is less than about 75% when compared to the maximum partial pressure at the first half of the pulse. In other embodiments, the partial pressure at the last half of the pulse is less than about 50% when compared to the maximum partial pressure at the first half of the pulse. In other embodiments, the partial pressure at the last half of the pulse is less than about 25% when compared to the maximum partial pressure at the first half of the pulse. The illustrated pulse can be cyclically repeated in a pulsed or cyclical chemical vapor etch process.

FIG. 3 illustrates a second etching mode, in which a second type or shape of pulse is delivered to the reactor 5. Unlike the first mode of FIG. 2, in which only a portion of the fill volume of the intermediate chamber 4 was used, in the second mode of FIG. 3, all or substantially all of the reactant vapor filling the intermediate chamber 4 may be used, e.g., may be delivered to the reaction chamber 5. As shown in FIG. 3, the valve V1 may be closed. The valve V2 can be opened and at least a portion of the dosage of reactant vapor contained in the intermediate chamber 4 can be transported to the reactor 5 until the pressure between the fill volume (e.g., intermediate chamber 4) and reactor 5 are the same (ΔP=0). The partial pressure of the vaporized reactant during this pulse period can be determined by the conductance of the needle valve V3 and the difference in pressure between the pressure in the intermediate chamber 4, P1, and the pressure in the reactor 5, P2. The difference in pressure is determined by the equation ΔP=P1−P2. During operation, the pressure differential ΔP may constantly change as the pressure P1 may decrease after opening the valve V2. Accordingly, partial pressure of reactant delivered to the reaction chamber 5 can also vary over time, also linearly if the conductance is kept constant. As depicted in FIG. 3, the partial pressure of the vaporized reactant may decrease linearly after the valve V2 is opened. In some embodiments, the partial pressure can decrease at a rate of more than 10% per second. For example, the partial pressure may decrease at a rate greater than about 25% per second, at a rate greater than about 50% per second, or greater than a rate of about 75% per second. In various embodiments, the partial pressure of the vaporized reactant may decrease in an about linear manner after the valve V2 is opened. Unlike the first mode shown in FIG. 2, in the second mode of FIG. 3, there may be no partial pressure tail in this pulsing mode. Dosage of the vaporized reactant can be determined by the equation [P1(0)−P2]V/T, where P1(0) is the intermediate chamber 4 pressure before opening V2 and P2 is the reactor pressure. The illustrated pulse can be cyclically repeated in a pulsed or cyclical chemical vapor etch process.

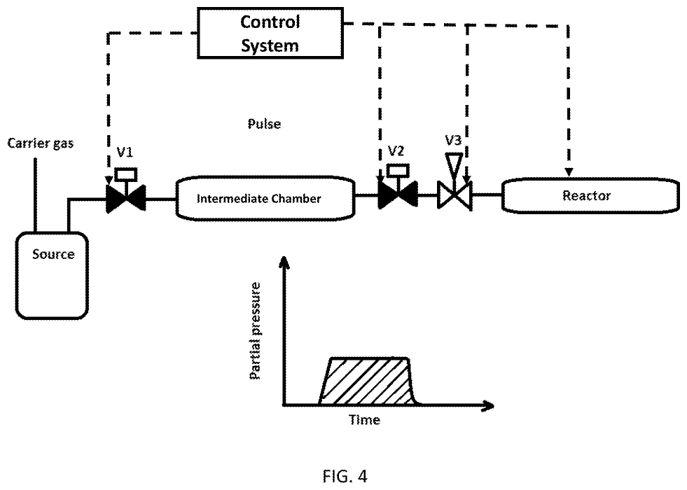

FIG. 4 illustrates a third etching mode, in which a third type or shape of pulse is delivered to the reactor 5. In the third mode shown in FIG. 4, both V1 and V2 are opened during the pulse, which transfers the vaporized reactant from the source 3, through the intermediate chamber 4, to the reactor 5. The partial pressure of reactant during the pulse time can be determined at least in part by the pressure in the source vessel 3 and the conductance of the needle valve V3. If the vaporization rate of the precursor in the source vessel 3 and the conductance are constant during the pulse, the partial pressure may also remain constant during the pulse. As depicted in FIG. 4, the precursor tail at the end of the pulse may also be present, for reasons generally similar to those explained above in connection with the precursor tail of FIG. 2. The illustrated pulse can be cyclically repeated in a pulsed or cyclical chemical vapor etch process. Operation of this third etching mode may not be affected by the presence of the intermediate chamber, relative to apparatuses without such a chamber, but demonstrates flexibility of operation of the apparatus to achieve these and other desired modes and provide additional variables to modulate to achieve the desired etching distribution and effect across the substrate within the reaction chamber. In other embodiments, operation of this third etching mode can be affected by the presence of the intermediate chamber, relative to apparatuses without such a chamber, but demonstrates flexibility of operation of the apparatus to achieve these and other desired modes and provide additional variables to modulate to achieve the desired etching distribution and effect across the substrate within the reaction chamber.

Beneficially, the systems and methods disclosed herein can provide for improved spatial uniformity and conformality in various types of etch procedure, such as ALE. The use of an intermediate chamber 4 between the source 3 and reactor 5 with the valves V1, V2, and V3 can provide for the control of overall dosage and partial pressure during the pulse. Different pulse modes can also be selected to provide desired pulse shapes to the reactor 5.

While certain embodiments of the inventions have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure. Accordingly, the scope of the present inventions is defined only by reference to the appended claims.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A method comprising:
providing a substrate inside a reaction chamber;
providing a source of etch reactant vapor upstream of and in fluid communication with an intermediate chamber, wherein the intermediate chamber is upstream of and in fluid communication with the reaction chamber;
supplying an etch reactant vapor from the source of etch reactant vapor to the intermediate chamber; and
etching the substrate by pulsing at least a portion of the etch reactant vapor from the intermediate chamber to the reaction chamber.

2. The method of claim 1, wherein supplying the etch reactant vapor to the intermediate chamber comprises:
opening a first valve disposed between the source of etch reactant vapor and the intermediate chamber.

3. The method of claim 1, wherein etching the substrate comprises:
closing a first valve disposed between the source of etch reactant vapor and the intermediate chamber; and
delivering the at least the portion of the etch reactant vapor in the intermediate chamber to the reaction chamber by opening a second valve disposed between the intermediate chamber and the reaction chamber.

4. The method of claim 1, wherein etching the substrate comprises:
closing a first valve disposed between the source of etch reactant vapor and the intermediate chamber; and
delivering substantially all of the etch reactant vapor in the intermediate chamber to the reaction chamber by opening a second valve disposed between the intermediate chamber and the reaction chamber.

5. The method of claim 1, wherein etching the substrate comprises:
opening a first valve disposed between the source of etch reactant vapor and the intermediate chamber; and
delivering the at least the portion of the etch reactant vapor in the intermediate chamber to the reaction chamber by opening a second valve disposed between the intermediate chamber and the reaction chamber.

6. The method of claim 1, wherein a first valve is disposed between the source of etch reactant vapor and the intermediate chamber;
wherein a second valve is disposed between the intermediate chamber and a third valve;
wherein the third valve is disposed between the second valve and the reaction chamber; and
wherein etching the substrate comprises:
controlling the third valve to adjust a flowrate of the etch reactant vapor to the reaction chamber.

7. The method of claim 6, wherein the third valve is a needle valve.

8. The method of claim 6, wherein etching the substrate further comprises:
controlling a first pressure of the etch reactant vapor in the reaction chamber based at least in part on the flowrate of the etch reactant vapor to the reaction chamber.

9. The method of claim 1, wherein etching the substrate further comprises:
controlling a pressure difference between:
a first pressure of the etch reactant vapor in the reaction chamber; and
a second pressure of the etch reactant vapor in the intermediate chamber.

10. The method of claim 9, wherein etching the substrate further comprises:
controlling a first valve disposed between the source of etch reactant vapor and the intermediate chamber; and
controlling a second valve disposed between the intermediate chamber and the reaction chamber.

11. The method of claim 10, wherein etching the substrate further comprises:
controlling the first valve to close and the second valve to open to transfer only a portion of a dosage, which is less than substantially all of the dosage, of the etch reactant vapor in the intermediate chamber to the reaction chamber in each pulse;
linearly increasing the pressure difference to a first difference level; and
after reaching the first difference level, linearly decreasing the pressure difference from the first difference level to a second difference level.

12. The method of claim 11, wherein the second difference level is substantially zero.

13. The method of claim 11, wherein the second difference level is non-zero.

14. The method of claim 13, wherein etching the substrate further comprises:
after reaching the second difference level, linearly decreasing the pressure difference from the second difference level to a third difference level that is substantially zero.

15. The method of claim 10, wherein etching the substrate further comprises:
controlling the first valve to close and the second valve to open to transfer substantially all of a dosage of the etch reactant vapor in the intermediate chamber to the reaction chamber in each pulse;
linearly increasing the pressure difference to a first difference level; and
after reaching the first difference level, linearly decreasing the pressure difference from the first difference level to a second difference level.

16. The method of claim 10, wherein etching the substrate further comprises:
controlling the first valve to open and the second valve to open at a same time during each pulse;
increasing the pressure difference to a first difference level;
after reaching the first difference level, maintaining the pressure difference at the first difference level for a time period; and
decreasing the pressure difference from the first difference level to a second difference level.

17. The method of claim 1, further comprising heating the intermediate chamber to a first temperature.

18. The method of claim 17, further comprising heating the source of etch reactant vapor to a second temperature greater than the first temperature.

19. The method of claim 1, further wherein etching the substrate comprises:
control a partial pressure of the etch reactant vapor based at least in part on a pressure difference between a first pressure in the intermediate chamber and a second pressure in the reaction chamber.

20. The method of claim 1, further comprising:
alternately delivering two different reactants in pulses to the reaction chamber for a controlled etching process.
